(19) United States
(12) Patent Application Publication
(10) Pub. No.: US 2026/0066878 A1
(43) Pub. Date: Mar. 5, 2026

(54) MULTIPLEXER

(71) Applicant: Murata Manufacturing Co., Ltd., Nagaokakyo-shi (JP)

(72) Inventors: Hiroshi MATSUBARA, Nagaokakyo-shi (JP); Masakazu TANI, Nagaokakyo-shi (JP); Atsushi ONO, Nagaokakyo-shi (JP); Masanori KATO, Nagaokakyo-shi (JP); Satoshi NAGATA, Nagaokakyo-shi (JP)

(73) Assignee: Murata Manufacturing Co., Ltd., Nagaokakyo-shi (JP)

(21) Appl. No.: 19/308,484

(22) Filed: Aug. 25, 2025

(30) Foreign Application Priority Data
Sep. 3, 2024 (JP) 2024-151406

(51) Int. Cl. H03H 9/70

(52) U.S. Cl. CPC H03H 9/70

(57) ABSTRACT

A multiplexer includes first and second filters are connected to a common terminal. The first filter includes series arm resonators disposed on a first series arm path and a first variable capacitance circuit connected in parallel to a first series arm resonator s11 that is connected and nearest to the common terminal. The first variable capacitance circuit includes a capacitor and a switch that are connected in series to each other. The second filter includes parallel arm resonators that are connected between a second series arm path and a ground and a second variable capacitance circuit connected in series to the parallel arm resonator that is connected and nearest to the common terminal. The second variable capacitance circuit includes a capacitor and a switch that are connected in parallel to each other.

### CROSS-REFERENCE TO RELATED APPLICATION

The present application claims priority to Japanese patent application JP2024-151406, filed Sep. 3, 2024, the entire contents of which being incorporated herein by reference.

### BACKGROUND

### 1. Field

The present disclosure relates to a multiplexer.

### 2. Description of the Related Art

A multiplexer disclosed in Japanese Unexamined Patent Application Publication No. 2023-58393 includes a first filter that has a passband of a mid-high band (MHB: 1710 to 2370 MHz) and a passband of Band 41 (2496 to 2690 MHz) and a second filter that has a passband of a wireless local area network (WLAN) 2.4 GHz band and uses acoustic wave resonators.

### SUMMARY

A frequency gap between the WLAN 2.4 GHz band and the Band 41 is 14 MHz, and a frequency gap between Band 53 (2483.5 to 2495 MHz), which has a frequency band between the Band 41 and a WiFi 2.4 GHz band, and the WiFi 2.4 GHz band, for example, is 1.5 MHz. For example, in the case where a signal in the WLAN 2.4 GHz band and the signal in the Band 53 are simultaneously transmitted, it is difficult for the multiplexer disclosed in Japanese Unexamined Patent Application Publication No. 2023-58393 to demultiplex the two signals because the frequency gap is small. That is, in some cases, it is difficult to simultaneously transmit the two signals such that the two signals can be demultiplexed in a simultaneous transmission mode in Band A and Band B and in a simultaneous transmission mode in the Band A and B and C that have a frequency gap smaller than a frequency gap between the Band A and the Band B.

In view of this, the present disclosure is directed to solving the problems described above and others. In particular, the present disclosure is directed to providing a multiplexer that is capable of simultaneously transmitting signals in two bands that have a small frequency gap such that the signals can be demultiplexed.

To realize this capability, a multiplexer according to an aspect of the present disclosure includes a common terminal, a first input-output terminal, a second input-output terminal, a first filter that is connected between the common terminal and the first input-output terminal, and a second filter that is connected between the common terminal and the second input-output terminal. The first filter includes one or more series arm resonators that are disposed on a first series arm path connecting the common terminal and the first input-output terminal to each other and that include an acoustic wave resonator, one or more parallel arm resonators that are connected between the first series arm path and a ground and that include an acoustic wave resonator, and a first variable capacitance circuit connected in parallel to a first series arm resonator that is connected and nearest to the common terminal among the one or more series arm resonators that are included in the first filter. The first variable capacitance circuit includes a first capacitor and a first switch that are connected in series to each other. The second filter includes one or more series arm resonators that are disposed on a second series arm path connecting the common terminal and the second input-output terminal to each other and that include an acoustic wave resonator, one or more parallel arm resonators that are connected between the second series arm path and the ground and that include an acoustic wave resonator, and a second variable capacitance circuit connected in series to a first parallel arm resonator that is connected and nearest to the common terminal among the one or more parallel arm resonators that are included in the second filter. The second variable capacitance circuit includes a second capacitor and a second switch that are connected in parallel to each other.

According to present disclosure, a multiplexer that is capable of simultaneously transmitting signals in two bands that have a small frequency gap such that the signals can be demultiplexed can be provided.

### BRIEF DESCRIPTION OF THE DRAWINGS

FIG. 1 illustrates an example of a circuit structure of a multiplexer according to an embodiment;

FIG. 2A and FIG. 2B are graphs illustrating the bandpass characteristic of a first filter according to the embodiment;

FIG. 3A and FIG. 3B illustrate the impedance characteristic of a series arm resonator unit and a Smith chart representing the impedance of the first filter according to the embodiment;

FIG. 4A and FIG. 4B are graphs illustrating the bandpass characteristic of a second filter according to the embodiment;

FIG. 5A and FIG. 5B illustrate the impedance characteristic of a parallel arm resonator unit and a Smith chart illustrating the impedance of the second filter according to the embodiment;

FIG. 6 illustrates a circuit structure of the multiplexer according to the embodiment;

FIG. 7 is a graph schematically illustrating the bandpass characteristic of a multiplexer in a first example;

FIG. 8 is a graph schematically illustrating the bandpass characteristic of a multiplexer in a second example;

FIG. 9 is a graph schematically illustrating the bandpass characteristic of a multiplexer in a third example;

FIG. 10 is a graph schematically illustrating the bandpass characteristic of a multiplexer in a fourth example;

FIG. 11 illustrates an example of a circuit structure of a multiplexer according to a modification to the embodiment;

FIG. 12A and FIG. 12B are plan views of the multiplexer according to the embodiment; and

FIG. 13 is a sectional view of the multiplexer according to the embodiment.

### DETAILED DESCRIPTION

Embodiments of the present disclosure will hereinafter be described in detail with reference to the drawings. The embodiments are described later as comprehensive or specific examples. In the embodiments described later, numerical values, shapes, materials, components, and the arrangement and connection form of the components, for example, are described by way of example and do not limit the present disclosure. Among the components according to the embodiments described later, components that are not recited in the independent claim are described as optional components. In the drawings, the dimensions of the components or ratios of the dimensions are not necessarily illustrated strictly.

The drawings are schematic diagrams appropriately including emphasis, omission, and adjustment in a ratio for describing the present disclosure and are not necessarily illustrate strictly, and some shapes, positional relationships, and ratios differ from actual ones. In the drawings, substantially like components are designated by using like reference characters, and a duplicated description is omitted or simplified in some cases.

As for a circuit structure according to the present disclosure, the case of “being connected” includes not only the case of being directly connected by using a connection terminal and/or a wiring conductor but also the case of being electrically connected with a matching device or a switch circuit interposed therebetween. The expression “connected between A and B” means being connected to both of A and B between A and B.

According to the present disclosure, a “terminal” means a point at which a conductor in an element ends. In the case where the impedance of a conductor between elements is sufficiently low, the terminal is interpreted as not only a single point but also a freely selected point (a node) on the conductor between the elements or the entire conductor.

As for circuit element arrangement according to the present disclosure, the expression “a circuit element A is disposed in series on a path B” means that a signal input terminal and a signal output terminal of the circuit element A are connected to two wiring lines that form at least a portion of the path B. At least one of the two wiring lines may be an electrode or a terminal.

In the drawings described later, an x-axis and a y-axis are perpendicular to each other along a plane parallel with a main surface of a module laminate. Specifically, in the case where the module laminate has a rectangular shape in plan view, the x-axis is parallel with a first side of the module laminate, and the y-axis is parallel with a second side of the module laminate perpendicular to the first side. A z-axis is perpendicular to the main surface of the module laminate, a positive direction thereof represents an upward direction, and a negative direction thereof represents a downward direction.

Terms that represent relationships between elements such as “parallel” and “perpendicular”, a term that represents the shape of an element such as “rectangular”, and a numeral range do not have only strict meanings but have substantially the same meanings including, for example, an error of about several percent.

As for the arrangement of components according to the present disclosure, a “plan view of a module laminate” means that an object orthographically projected on an xy plane is viewed from a positive position on the z-axis. The expression “A overlaps B in plan view” means that at least a portion of the region of A orthographically projected on the xy plane overlaps at least a portion of the region of B orthographically projected on the xy plane. The expression “A is disposed between B and C” means that at least one of multiple lines that connect a freely selected point in B and a freely selected point in C to each other passes through A.

As for the arrangement of the components according to the present disclosure, the expression “a component is disposed in, on, or along a substrate” means that the component is disposed on or along a main surface of the substrate or that the component is disposed in the substrate. The expression “a component is disposed on or along a main surface of a substrate” means that the component is in contact with the main surface of the substrate or that the component is not in contact with the main surface but is disposed above the main surface (for example, the component is stacked on another component that is in contact with the main surface). The expression “a component is disposed on or along a main surface of a substrate” may mean that the component is disposed in a recessed portion that is formed on the main surface. The expression “a component is disposed in a substrate” means that the component is encapsulated in a module laminate, that the entire component is disposed between both main surfaces of the substrate but a portion of the component is not covered by the substrate, or that only a portion of the component is disposed in the substrate.

According to the embodiments described later, the passband of a band pass filter is defined as a frequency band between two frequencies that are 3 dB higher than the minimum insertion loss within the passband. The elimination band of a band elimination filter is defined as a frequency band between two frequencies when the insertion loss is 10 dB in which the insertion loss is continuously 10 dB or more.

An acoustic wave resonator unit is defined as (1) a resonant circuit that includes an acoustic wave resonator and a circuit (or a circuit element) that is connected in parallel to the acoustic wave resonator (a parallel connection circuit of the acoustic wave resonator and the circuit (or the circuit element)), (2) a resonant circuit that includes an acoustic wave resonator and a circuit (or a circuit element) connected to one of two input-output terminals of the acoustic wave resonator and that has a structure in which another circuit (and another circuit element) and the ground are not connected to a connection node that connects the acoustic wave resonator and the circuit (or the circuit element) to each other (a series connection circuit of the acoustic wave resonator and the circuit (or the circuit element)), (3) a resonant circuit that includes multiple acoustic wave resonators connected in parallel to each other (a parallel connection circuit of a split resonator), or (4) a resonant circuit that includes multiple acoustic wave resonators connected in series to each other and that has a structure in which a circuit (and a circuit element) other than the multiple acoustic wave resonators and the ground are not connected to a connection node that connects the multiple acoustic wave resonators to each other (a series connection circuit of a split resonator).

According to the embodiments of the present disclosure, a resonant band width means a difference between a resonant frequency and an anti-resonant frequency of an acoustic wave resonator.

The resonant frequency and the anti-resonant frequency according to the embodiments and a modification are derived, for example, in a manner in which a RF probe is brought into contact with two input-output electrodes of an acoustic wave resonator or an acoustic wave resonator unit with the acoustic wave resonator or the acoustic wave resonator unit disconnected from another circuit element, and a reflection characteristic (the impedance characteristic) is measured by, for example, a network analyzer.

According to the present disclosure, a “band” means at least an uplink operation band or a downlink operation band of a frequency band that is defined in advance by, for example, a standardizing body (such as 3GPP (registered trademark) or Institute of Electrical and Electronics Engineers (IEEE)) for a communication system that is established by using a radio access technology (RAT). According to the present embodiment, examples of a communication system can include a long term evolution (LTE) system, a 5th generation (5G)-new radio (NR) system, and a wireless local area network (WLAN) system but are not limited thereto. The uplink operation band of the frequency band means a frequency range that is specified for uplink in the frequency band. The downlink operation band of the frequency band means a frequency range that is specified for downlink in the frequency band.

### Embodiment

### 1. Specific Circuit Structure of Multiplexer

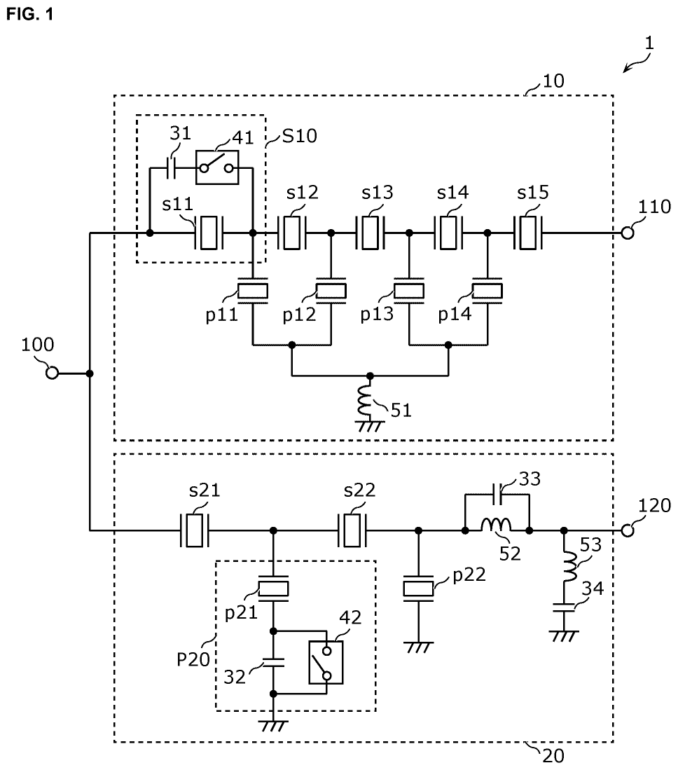

FIG. 1 illustrates an example of a circuit structure of a multiplexer 1 according to the embodiment. The multiplexer 1 includes filters 10 and 20, a common terminal 100, and input-output terminals 110 (a first input-output terminal) and 120 (a second input-output terminal). The common terminal 100 is connected to, for example, an antenna.

The filter 10 is an example of a first filter and is connected between the common terminal 100 and the input-output terminal 110. The filter 20 is an example of a second filter and is connected between the common terminal 100 and the input-output terminal 120.

The filter 10 includes series arm resonators s11, s12, s13, s14, and s15, parallel arm resonators p11, p12, p13, and p14, a capacitor 31, a switch 41, and an inductor 51.

The series arm resonators s11 to s15 include respective acoustic wave resonators and are disposed on a first series arm path that connects the common terminal 100 and the input-output terminal 110 to each other. The parallel arm resonators p11 to p14 include respective acoustic wave resonators and are connected between the first series arm path and the ground.

The capacitor 31 is an example of a first capacitor, and the switch 41 is an example of a first switch. The capacitor 31 and the switch 41 are connected in series and form a first variable capacitance circuit. The first variable capacitance circuit is connected in parallel to the series arm resonator s11. The series arm resonator s11 is an example of a first series arm resonator and is connected and nearest to the common terminal 100 among the series arm resonators s11 to s15 that are included in the filter 10. The series arm resonator s11, the capacitor 31, and the switch 41 form a series arm resonator unit S10.

The inductor 51 is connected between the parallel arm resonators p11 to p14 and the ground.

The filter 20 includes series arm resonators s21 and s22, parallel arm resonators p21 and p22, capacitors 32, 33, and 34, a switch 42, and inductors 52 and 53.

The series arm resonators s21 and s22 include respective acoustic wave resonators and are disposed on a second series arm path that connects the common terminal 100 and the input-output terminal 120 to each other. The parallel arm resonators p21 and p22 include respective acoustic wave resonators and are connected between the second series arm path and the ground.

The capacitor 32 is an example of a second capacitor, and the switch 42 is an example of a second switch. The capacitor 32 and the switch 42 are connected in parallel to each other and form a second variable capacitance circuit. The second variable capacitance circuit is connected in series to the parallel arm resonator p21. The parallel arm resonator p21 is an example of a first parallel arm resonator and is connected and nearest to the common terminal 100 among the parallel arm resonators p21 and p22 that are included in the filter 20. The parallel arm resonator p21, the capacitor 32, and the switch 42 form a parallel arm resonator unit P20.

The inductor 52 and the capacitor 33 are connected in parallel to each other and are disposed in series on the second series arm path between the series arm resonator s22 and the input-output terminal 120. The inductor 53 and the capacitor 34 are connected in series to each other and are connected between the ground and the second series arm path between the series arm resonator s22 and the input-output terminal 120.

With the structure described above, the filter 10 serves as, for example, a ladder band pass filter that includes an acoustic wave resonator, and the filter 20 serves as, for example, a ladder band elimination filter that includes an acoustic wave resonator.

The filters 10 and 20 are not limited to the circuit structure illustrated in FIG. 1, provided that the filter 10 includes the series arm resonator unit S10, one or more series arm resonators, and one or more parallel arm resonators, and the filter 20 includes the parallel arm resonator unit P20, one or more series arm resonators, and one or more parallel arm resonators.

The filter 10 may be a band elimination filter, and the filter 20 may be a band pass filter.

### 2. Example of Use of Multiplexer 1

An existing front-end circuit that is proposed transmits signals in the MHB (1710 to 2370 MHz), the WLAN 2.4 GHz band (WiFi (registered trademark) 2.4 GHz band: for example, 2400 to 2482 MHz), and the Band 41 for the long term evolution (LTE) or n41 (2496 to 2690 MHz) for the 5th generation new radio (5GNR). A frequency gap between the MHB and the WLAN 2.4 GHz band is 30 MHz (a fractional band width of 1.3%), and a frequency gap between the WLAN 2.4 GHz band and the Band 41 is 14 MHz (a fractional band width of 0.6%). An acoustic wave resonator that has a high resonant Q-value is used for a front-end circuit that simultaneously transmits the signals in the three frequency bands described above such that the signals can be demultiplexed.

In the description below in the specification, the Band A for the LTE or nA for the 5GNR is referred to simply as the Band A in some cases.

In recent years, the Band 53 (2483.5 to 2495 MHz) that includes a frequency band between the WLAN 2.4 GHz band and the Band 41 has been released. There is a need for a front-end circuit that simultaneously transmits the signals in the MHB, the WLAN 2.4 GHz band, and the Band 41 and that simultaneously transmits the signal in the WLAN 2.4 GHz band and a signal in the Band 53. A frequency gap between the WLAN 2.4 GHz band and the Band 53 is 1.5 MHz (a fractional band width of 0.06%), and it is accordingly difficult for an existing front-end circuit that uses an acoustic wave resonator to simultaneously transmit the signal in the WLAN 2.4 GHz band and the signal in the Band 53 such that the signals can be demultiplexed.

The multiplexer 1 according to the present embodiment, however, is capable of changing the passbands (or the elimination bands) of the filters 10 and 20 for (1) simultaneously transmitting the signal in the WLAN 2.4 GHz band and the signal in the Band 41 (referred to bellow as a mode A) and (2) simultaneously transmitting the signal in the WLAN 2.4 GHz band and the signal in the Band 53 (referred to below as a mode B). This enables a frequency gap between the two signals that are simultaneously transmitted to be ensured in the mode A and the mode B, and accordingly, the two signals can be simultaneously transmitted such that the signals can be demultiplexed. The bandpass characteristic of the multiplexer 1 according to the present embodiment will be described in detail below.

### 3. Bandpass Characteristic of Multiplexer 1

A basic operating principle of a ladder band pass filter that uses an acoustic wave resonator will now be described.

A parallel arm resonator has a resonant frequency frp at which the impedance is minimized and an anti-resonant frequency fap (>frp) at which the impedance is maximized. A series arm resonator has a resonant frequency frs at which the impedance is minimized and an anti-resonant frequency fas (>frs>frp) at which the impedance is maximized. As for the series arm resonator and the parallel arm resonator that have the resonance characteristics described above, the anti-resonant frequency fap of the parallel arm resonator and the resonant frequency frs of the series arm resonator are typically close to each other. Consequently, a band close to the resonant frequency frp at which the impedance of the parallel arm resonator is close to 0 is a low-frequency elimination band. As for an increased frequency, the impedance of the parallel arm resonator increases at a frequency close to the anti-resonant frequency fap, and the impedance of the series arm resonator is close to 0 at a frequency close to the resonant frequency frs. Consequently, a frequency close to a range from the anti-resonant frequency fap to the resonant frequency frs is in a signal pass band regarding a signal path that is a series arm path. This enables the electromechanical coupling coefficient and electrode parameters of the acoustic wave resonator to be reflected on a passband. As for a further increased frequency, a band close to the anti-resonant frequency fas at which the impedance of the series arm resonator increases is a high-frequency elimination band.

A basic operating principle of a ladder band elimination filter that uses an acoustic wave resonator will now be described.

The series arm resonator has the resonant frequency frs at which the impedance is minimized and the anti-resonant frequency fas (>frs) at which the impedance is maximized. The parallel arm resonator has the resonant frequency frp at which the impedance is minimized and the anti-resonant frequency fap (>frp>frs) at which the impedance is maximized. As for the series arm resonator and the parallel arm resonator that have the resonance characteristics described above, the anti-resonant frequency fas of the series arm resonator and the resonant frequency frp of the parallel arm resonator are typically close to each other. Consequently, a band close to the resonant frequency frs at which the impedance of the series arm resonator is close to 0 is a low-frequency pass band. As for an increased frequency, the impedance of the series arm resonator increases at a frequency close to the anti-resonant frequency fas, and the impedance of the parallel arm resonator is close to 0 at a frequency close to the resonant frequency frp. Consequently, a frequency close to a range from the anti-resonant frequency fas to the resonant frequency frp is in a signal elimination band regarding a signal path that is a series arm path. This enables the electromechanical coupling coefficient and electrode parameters of the acoustic wave resonator to be reflected on an elimination band. As for a further increased frequency, a band close to the anti-resonant frequency fap at which the impedance of the parallel arm resonator increases is a high-frequency pass band.

As for the series arm resonator and the parallel arm resonator, the impedance of each resonator is capacitive (C) in a frequency band lower than the resonant frequency, and the impedance of each resonator is inductive (L) in a frequency band higher than the resonant frequency and lower than the anti-resonant frequency. The impedance of each resonator is capacitive in a frequency band higher than the anti-resonant frequency.

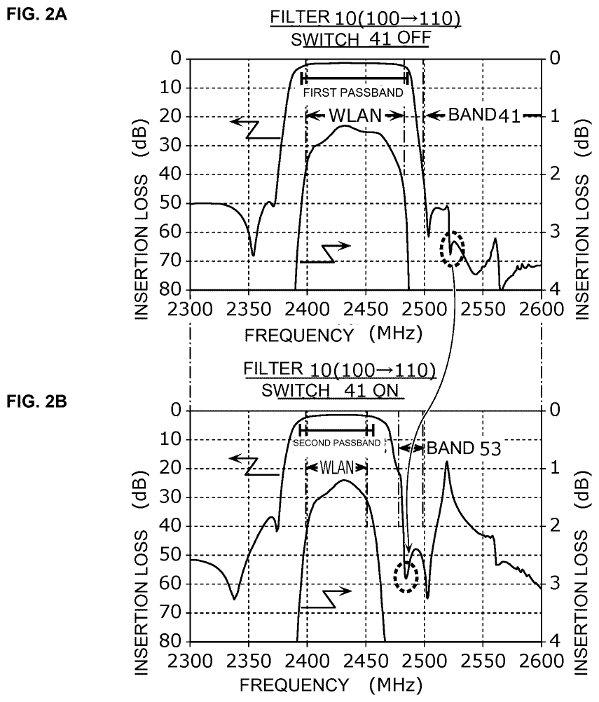

FIG. 2A and FIG. 2B are graphs illustrating the bandpass characteristic of the filter 10 according to the embodiment. FIG. 2A illustrates the bandpass characteristic of the filter 10 between the common terminal 100 and the input-output terminal 110 in the case where the switch 41 is in a non-conducting state. FIG. 2B illustrates the bandpass characteristic of the filter 10 between the common terminal 100 and the input-output terminal 110 in the case where the switch 41 is in a conducting state.

As illustrated in FIG. 2A, in the case where the switch 41 is in the non-conducting state, the filter 10 has a first passband that includes the WLAN 2.4 GHz band (2400 to 2482 MHz). An attenuation band higher than the first passband includes the Band 41.

As illustrated in FIG. 2B, in the case where the switch 41 is in the conducting state, the filter 10 has a second passband that includes a part of the WLAN 2.4 GHz band (2400 to 2450 MHz). An attenuation band higher than the second passband includes the Band 53.

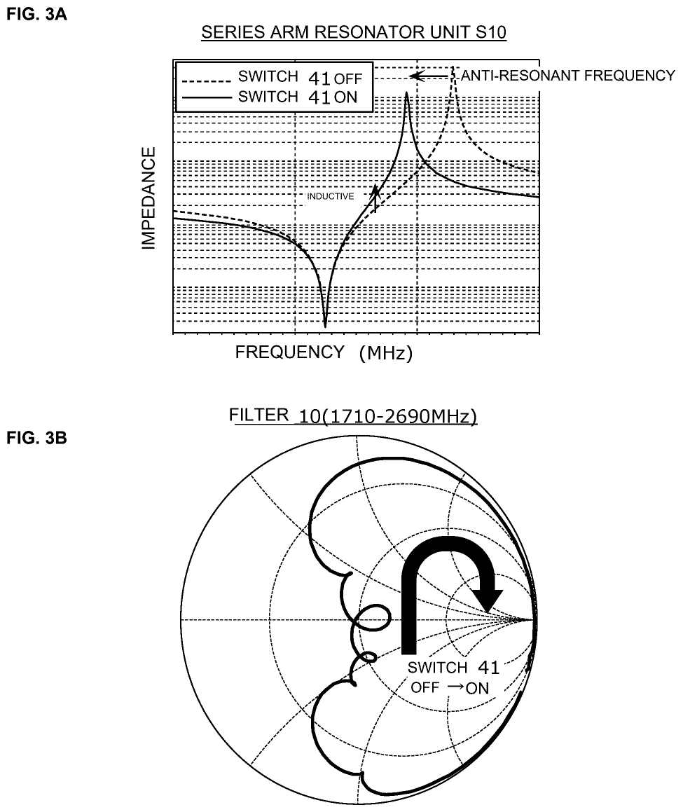

FIG. 3A illustrates the impedance characteristic of the series arm resonator unit S10 that is included in the filter 10, and FIG. 3B illustrates a Smith chart representing the impedance of the filter 10 according to the embodiment.

As illustrated in FIG. 3A, in the case where the switch 41 is in the non-conducting state, the resonance characteristics of the series arm resonator unit S10 are the same as the resonance characteristics of the series arm resonator s11. In this case, as illustrated in FIG. 2A, the filter 10 has the first passband.

In the case where the switch 41 is in the conducting state, the capacitor 31 is connected in parallel to the series arm resonator s11 at the series arm resonator unit S10, the anti-resonant frequency consequently shifts to a lower frequency, and the resonant band width of the series arm resonator unit S10 decreases. For this reason, in the case where the switch 41 is in the conducting state, the resonant band width of the series arm resonator s11 that defines the high-frequency range of the passband decreases, and consequently, the filter 10 has the second passband that has a high-frequency limit lower than the high-frequency limit of the first passband as illustrated in FIG. 2B.

As illustrated in FIG. 3A, the impedance in a band between the resonant frequency and the anti-resonant frequency of the series arm resonator unit S10 is strongly inductive with the switch 41 being in the conducting state. Consequently, as illustrated in FIG. 3B, the impedance of the filter 10 when viewed from the common terminal 100 rotates clockwise particularly at frequencies close to high frequencies in the passband. As a result, the frequency band in an open state shifts toward a low-frequency range, the high-frequency range of the first passband changes from the passband into the attenuation band (inside a dashed line in FIG. 2B).

As for the filter 10 according to the present embodiment, the series arm resonator s11 that is connected and nearest to the common terminal 100 among the series arm resonators s11 to s15 has a function of changing the anti-resonant frequency. The impedance of the series arm resonator s11 nearest to the common terminal 100 most dominantly influences in the overall impedance characteristic of the filter 10 when viewed from the common terminal 100. For this reason, as for the filter 20 that is connected to the common terminal 100 as in the filter 10, the bandpass characteristic of the filter 20 can be most effectively inhibited from being degraded due to the bandpass characteristic of the filter 10. For this reason, the multiplexer 1 that is capable of changing the passband and that has a low loss can be provided.

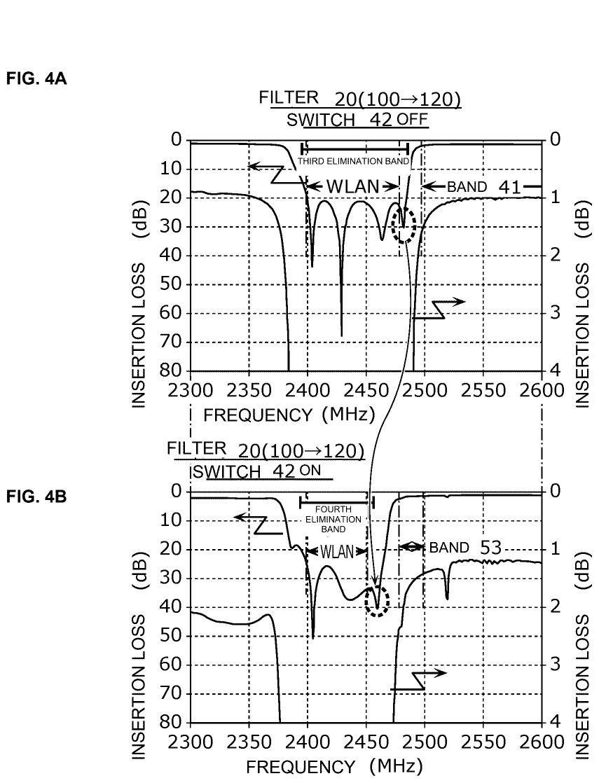

FIG. 4A and FIG. 4B are graphs illustrating the bandpass characteristic of the filter 20 according to the embodiment. FIG. 4A illustrates the bandpass characteristic of the filter 20 between the common terminal 100 and the input-output terminal 120 in the case where the switch 42 is in the non-conducting state. FIG. 4B illustrates the bandpass characteristic of the filter 20 between the common terminal 100 and the input-output terminal 120 in the case where the switch 42 is in the conducting state.

As illustrated in FIG. 4A, in the case where the switch 42 is in the non-conducting state, the filter 20 has a third elimination band that includes the WLAN 2.4 GHz band (2400 to 2482 MHz). A passband higher than the third elimination band includes the Band 41.

As illustrated in FIG. 4B, in the case where the switch 42 is in the conducting state, the filter 20 has a fourth elimination band that includes a part of the WLAN 2.4 GHz band (2400 to 2450 MHz). A passband higher than the fourth elimination band includes the Band 53.

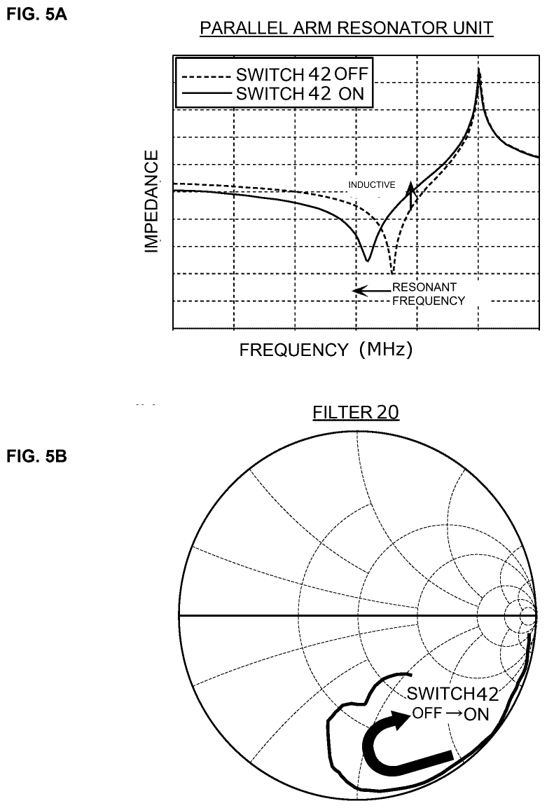

FIG. 5A illustrates the impedance characteristic of the parallel arm resonator unit P20 that is included in the filter 20, and FIG. 5B illustrates a Smith chart illustrating the impedance of the filter 20 according to the embodiment.

As illustrated in FIG. 5A, in the case where the switch 42 is in the non-conducting state, the resonance characteristics of the parallel arm resonator unit P20 are the same as resonance characteristics when the capacitor 32 is connected in series to the parallel arm resonator p21. Consequently, the resonant frequency of the parallel arm resonator unit P20 shifts to a higher frequency relative to the resonant frequency of the parallel arm resonator p21 alone, and the resonant band width of the parallel arm resonator unit P20 decreases. In this case, as illustrated in FIG. 4A, the filter 20 has the third elimination band.

In the case where the switch 42 is in the conducting state, both ends of the capacitor 32 are short-circuited, and consequently, the resonance characteristics of the parallel arm resonator unit P20 are the same as the resonance characteristics of the parallel arm resonator p21. In this case, as illustrated in FIG. 4B, the filter 20 has the fourth elimination band.

As illustrated in FIG. 5A, the impedance in a band between the resonant frequency and the anti-resonant frequency of the parallel arm resonator unit P20 is strongly inductive with the switch 42 being in the conducting state. Consequently, as illustrated in FIG. 5B, the impedance of the filter 20 when viewed from the common terminal 100 rotates clockwise particularly at frequencies close to high frequencies in the elimination bands. As a result, the impedance at frequencies close to high frequencies in the third elimination band shifts toward the center of the Smith chart, and a change into the passband occurs (inside a dashed line in FIG. 4A).

As for the filter 20 according to the present embodiment, the parallel arm resonator p21 that is connected and nearest to the common terminal 100 among the parallel arm resonators p21 and p22 has a function of changing the resonant frequency. The impedance of the parallel arm resonator p21 nearest to the common terminal 100 is most dominant in the impedance of the filter 20 when viewed from the common terminal 100. For this reason, as for the filter 10 that is connected to the common terminal 100 as in the filter 20, the bandpass characteristic of the filter 10 can be most effectively inhibited from being degraded due to the bandpass characteristic of the filter 20. For this reason, the multiplexer 1 that is capable of changing the passband and that has a low loss can be provided.

As for the multiplexer 1 according to the present embodiment, the switch 42 is in the conducting state in the case where the switch 41 is in the conducting state, and the switch 42 is in the non-conducting state in the case where the switch 41 is in the non-conducting state.

In the case where the switches 41 and 42 are in the non-conducting state, the filter 10 has the first passband as illustrated in FIG. 2A, and the filter 20 has the third elimination band as illustrated in FIG. 4A. That is, the high-frequency limit of the third elimination band is higher than the high-frequency limit of the first passband. This enables a frequency gap between the first passband of the filter 10 and the passband in the high-frequency range of the third elimination band of the filter 20 to be ensured, and accordingly, the signal of the WLAN 2.4 GHz band and the signal in the Band 41 can be simultaneously transmitted such that the signals can be demultiplexed, for example, in a manner in which the filter 10 allows the signal in the WLAN 2.4 GHz band (2400 to 2482 MHz) to pass, and the filter 20 allows the signal in the Band 41 to pass. In other words, the series arm resonator unit S10 and the parallel arm resonator unit P20 are capable of adjusting the passbands (and the elimination bands) of the band pass filter and the band elimination filter, and the multiplexer 1 that transmits a signal in an increased range of frequency band with a low loss can be provided.

In the case where the switches 41 and 42 are in the conducting state, the filter 10 has the second passband as illustrated in FIG. 2B, and the filter 20 has the fourth elimination band as illustrated in FIG. 4B. That is, the high-frequency limit of the fourth elimination band is higher than the high-frequency limit of the second passband. This enables a frequency gap between the second passband of the filter 10 and the passband in the high-frequency range of the fourth elimination band of the filter 20 to be ensured, and accordingly, the signal in the WLAN 2.4 GHz band and the signal in the Band 53 can be simultaneously transmitted such that the signals can be demultiplexed, for example, in a manner in which the filter 10 allows the signal in a part of the WLAN 2.4 GHz band (2400 to 2450 MHz) to pass, and the filter 20 allows the signal in the Band 53 to pass.

### 4. Circuit Structure of Multiplexer 1

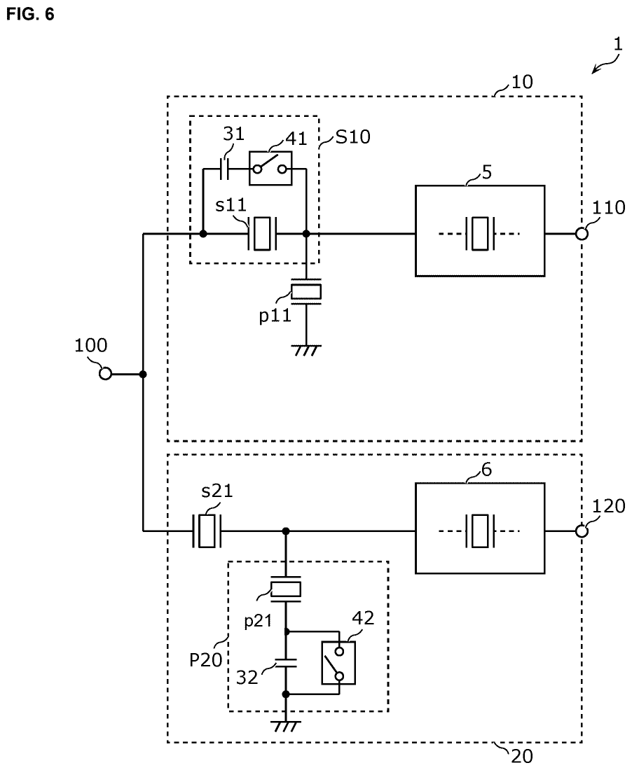

FIG. 6 illustrates the circuit structure of the multiplexer 1 according to the embodiment. As for the multiplexer 1 illustrated in FIG. 6, different components included in a multiplexer according to the present disclosure are illustrated, while other unchanged components from the multiplexer 1 illustrated in FIG. 1 are not repeated. As illustrated in FIG. 6, the multiplexer 1 includes the filters 10 and 20, the common terminal 100, the input-output terminals 110 (the first input-output terminal) and 120 (the second input-output terminal). Components of the multiplexer 1 illustrated in FIG. 6 that are the same as those of the multiplexer 1 illustrated in FIG. 1 will not be described below, but different components will be mainly described.

The filter 10 includes the series arm resonator unit S10, the parallel arm resonator p11, and an acoustic wave resonant circuit 5. The acoustic wave resonant circuit 5 includes an acoustic wave resonator. It is not necessary to include the acoustic wave resonant circuit 5. The filter 10 changes the passband or the elimination band by switching the conducting state and the non-conducting state of the switch 41.

The filter 20 includes the parallel arm resonator unit P20, the series arm resonator s21, and an acoustic wave resonant circuit 6. The acoustic wave resonant circuit 6 includes an acoustic wave resonator. It is not necessary to include the acoustic wave resonant circuit 6. The filter 20 changes the passband or the elimination band by switching the conducting state and the non-conducting state of the switch 42.

### 5. Multiplexer in First Example

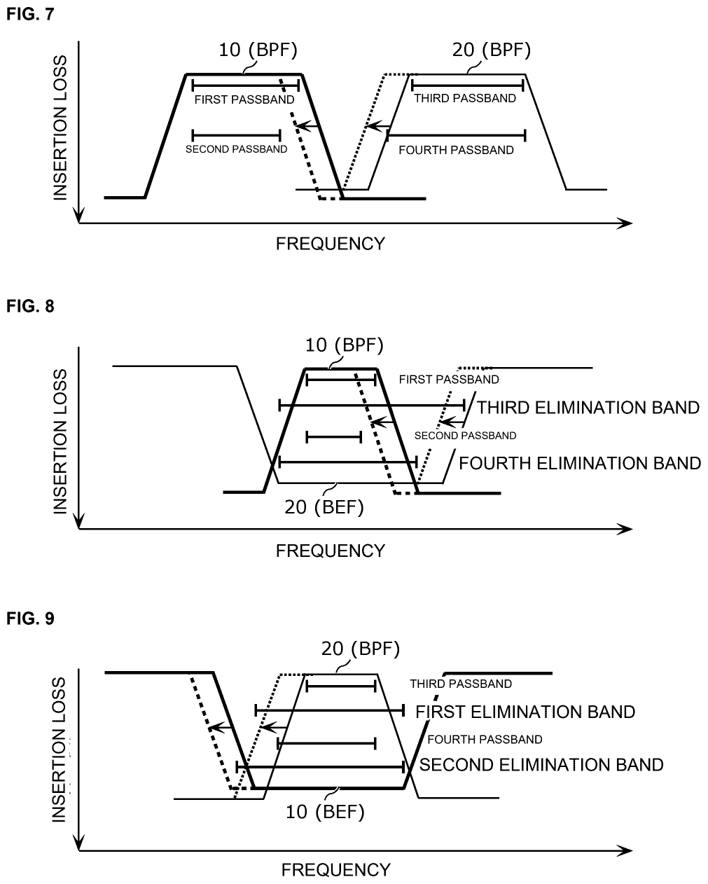

In a first example, the multiplexer 1 includes the circuit structure of the multiplexer 1 illustrated in FIG. 6. FIG. 7 is a graph schematically illustrating the bandpass characteristic of the multiplexer 1 in the first example. As for the multiplexer 1 in this example, the filter 10 is a band pass filter capable of changing the first passband and the second passband that has a high-frequency limit lower than the high-frequency limit of the first passband. The filter 10 has the first passband in the case where the switch 41 is in the non-conducting state and has the second passband in the case where the switch 41 is in the conducting state.

The filter 20 is a band pass filter capable of changing a third passband and a fourth passband that has a low-frequency limit lower than the low-frequency limit of the third passband. The filter 20 has the third passband in the case where the switch 42 is in the non-conducting state and has the fourth passband in the case where the switch 42 is in the conducting state.

The low-frequency limit of the third passband is higher than the high-frequency limit of the first passband, and the low-frequency limit of the fourth passband is higher than the high-frequency limit of the second passband.

This enables a frequency gap between the first passband and the third passband to be ensured in the case where the switches 41 and 42 are in the non-conducting state, and accordingly, the signal that passes through the filter 10 and the signal that passes through the filter 20 can be simultaneously transmitted such that the signals can be demultiplexed. This also enables a frequency gap between the second passband and the fourth passband to be ensured in the case where the switches 41 and 42 are in the conducting state, and accordingly, the signal that passes through the filter 10 and the signal that passes through the filter 20 can be simultaneously transmitted such that the signals can be demultiplexed.

For example, the first passband includes the WLAN 2.4 GHz band (2400 to 2482 MHz). For example, the second passband includes a part of the WLAN 2.4 GHz band (2400 to 2450 MHz). For example, the third passband includes the Band 41. For example, the fourth passband includes the Band 53.

This enables the signal in the WLAN 2.4 GHz band and the signal in the Band 41 to be simultaneously transmitted such that the signals can be demultiplexed and enables the signal in the WLAN 2.4 GHz band and the signal in the Band 53 to be simultaneously transmitted such that the signals can be demultiplexed.

### 6. Multiplexer in Second Example

In a second example, the multiplexer 1 has the circuit structure of the multiplexer 1 illustrated in FIG. 6. FIG. 8 is a graph schematically illustrating the bandpass characteristic of the multiplexer 1 in the second example. As for the multiplexer 1 in this example, the filter 10 is a band pass filter capable of changing the first passband and the second passband that has a high-frequency limit lower than the high-frequency limit of the first passband. The filter 10 has the first passband in the case where the switch 41 is in the non-conducting state and has the second passband in the case where the switch 41 is in the conducting state.

The filter 20 is a band elimination filter capable of changing the third elimination band and the fourth elimination band that has a high-frequency limit lower than the high-frequency limit of the third elimination band. The filter 20 has the third elimination band in the case where the switch 42 is in the non-conducting state and has the fourth elimination band in the case where the switch 42 is in the conducting state.

The frequency of the high-frequency limit of the third elimination band is equal to or higher than the frequency of the high-frequency limit of the first passband, and the frequency of the high-frequency limit of the fourth elimination band is equal to or higher than the frequency of the high-frequency limit of the second passband.

This enables a frequency gap between the first passband and the passband of the filter 20 in the high-frequency range of the third elimination band to be ensured in the case where the switches 41 and 42 are in the non-conducting state, and accordingly, the signal that passes through the filter 10 and the signal that passes through the filter 20 can be simultaneously transmitted such that the signals can be demultiplexed. This also enables a frequency gap between the second passband and the passband of the filter 20 in the high-frequency range of the fourth elimination band to be ensured in the case where the switches 41 and 42 are in the conducting state, the signal that passes through the filter 10 and the signal that passes through the filter 20 can be simultaneously transmitted such that the signals can be demultiplexed.

For example, the first passband and the third elimination band include the WLAN 2.4 GHz band (2400 to 2482 MHz). For example, the passband of the filter 20 in the high-frequency range of the third elimination band includes the Band 41. For example, the second passband includes a part of the WLAN 2.4 GHz band (2400 to 2450 MHz). For example, the passband of the filter 20 in the high-frequency range of the fourth elimination band includes the Band 53.

This enables the signal in the WLAN 2.4 GHz band and the signal in the Band 41 to be simultaneously transmitted such that the signals can be demultiplexed and enables the signal in the WLAN 2.4 GHz band and the signal in the Band 53 to be simultaneously transmitted such that the signals can be demultiplexed.

### 7. Multiplexer in Third Example

In a third example, the multiplexer 1 has the circuit structure of the multiplexer 1 illustrated in FIG. 6. FIG. 9 is a graph schematically illustrating the bandpass characteristic of the multiplexer 1 in the third example. As for the multiplexer 1 in this example, the filter 10 is a band elimination filter capable of changing a first elimination band and a second elimination band that has a low-frequency limit lower than the low-frequency limit of the first elimination band. The filter 10 has the first elimination band in the case where the switch 41 is in the non-conducting state and has the second elimination band in the case where the switch 41 is in the conducting state.

The filter 20 is a band pass filter capable of changing the third passband and the fourth passband that has a low-frequency limit lower than the low-frequency limit of the third passband. The filter 20 has the third passband in the case where the switch 42 is in the non-conducting state and has the fourth passband in the case where the switch 42 is in the conducting state.

The frequency of the low-frequency limit of the first elimination band is equal to or lower than the frequency of the low-frequency limit of the third passband, and the frequency of the low-frequency limit of the second elimination band is equal to or lower than the frequency of the low-frequency limit of the fourth passband.

This enables a frequency gap between the passband of the filter 10 in the low-frequency range of the first elimination band and the third passband in the case where the switches 41 and 42 are in the non-conducting state, and accordingly, the signal that passes through the filter 10 and the signal that passes through the filter 20 can be simultaneously transmitted such that the signals can be demultiplexed. This also enables a frequency gap between the passband of the filter 10 in the low-frequency range of the second elimination band and the fourth passband to be ensured in the case where the switches 41 and 42 are in the conducting state, and accordingly, the signal that passes through the filter 10 and the signal that passes through the filter 20 can be simultaneously transmitted such that the signals can be demultiplexed.

For example, the first elimination band and the third passband include the Band 41. For example, the passband of the filter 10 in the low-frequency range of the first elimination band includes the WLAN 2.4 GHz band (2400 to 2482 MHz). For example, the second elimination band and the fourth passband include the Band 53. For example, the passband of the filter 10 in the low-frequency range of the second elimination band includes a part of the WLAN 2.4 GHz band (2400 to 2450 MHz).

This enables the signal in the WLAN 2.4 GHz band and the signal in the Band 41 to be simultaneously transmitted such that the signals can be demultiplexed and enables the signal in the WLAN 2.4 GHz band and the signal in the Band 53 to be simultaneously transmitted such that the signals can be demultiplexed.

### 8. Multiplexer in Fourth Example

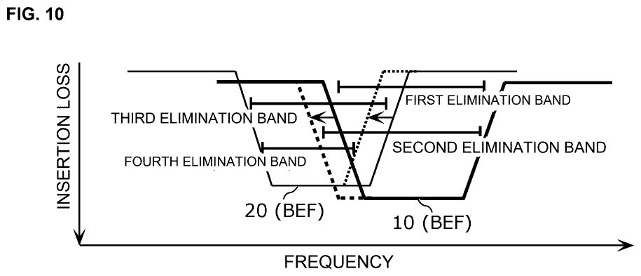

In a fourth example, the multiplexer 1 has the circuit structure of the multiplexer 1 illustrated in FIG. 6. FIG. 10 is a graph schematically illustrating the bandpass characteristic of the multiplexer 1 in the fourth example. As for the multiplexer 1 in this example, the filter 10 is a band elimination filter capable of changing the first elimination band and the second elimination band that has a low-frequency limit lower than the low-frequency limit of the first elimination band. The filter 10 has the first elimination band in the case where the switch 41 in the non-conducting state and has the second elimination band in the case where the switch 41 is in the conducting state.

The filter 20 is a band elimination filter capable of changing the third elimination band and the fourth elimination band that has a high-frequency limit lower than the high-frequency limit of the third elimination band. The filter 20 has the third elimination band in the case where the switch 42 is in the non-conducting state and has the fourth elimination band in the case where the switch 42 is in the conducting state.

The low-frequency limit of the first elimination band is lower than the high-frequency limit of the third elimination band, and the low-frequency limit of the second elimination band is lower than the high-frequency limit of the fourth elimination band.

This enables a frequency gap between the passband of the filter 10 in the low-frequency range of the first elimination band and the passband of the filter 20 in the high-frequency range of the third elimination band to be ensured in the case where the switches 41 and 42 are in the non-conducting state, and accordingly, the signal that passes through the filter 10 and the signal that passes through the filter 20 can be simultaneously transmitted such that the signals can be demultiplexed. This also enables a frequency gap between the passband of the filter 10 in the low-frequency range of the second elimination band and the passband of the filter 20 in the high-frequency range of the fourth elimination band to be ensured in the case where the switches 41 and 42 are in the conducting state, and accordingly, the signal that passes through the filter 10 and the signal that passes through the filter 20 can be simultaneously transmitted such that the signals can be demultiplexed.

For example, the first elimination band includes the Band 41. For example, the passband of the filter 10 in the low-frequency range of the first elimination band includes the WLAN 2.4 GHz band (2400 to 2482 MHz). For example, the second elimination band includes the Band 53. For example, the passband of the filter 10 in the low-frequency range of the second elimination band includes a part of the WLAN 2.4 GHz band (2400 to 2450 MHz). For example, the third elimination band includes the WLAN 2.4 GHz band (2400 to 2482 MHz). For example, the passband of the filter 20 in the high-frequency range of the third elimination band includes the Band 41. For example, the fourth elimination band includes a part of the WLAN 2.4 GHz band (2400 to 2450 MHz). For example, the passband of the filter 20 in the high-frequency range of the fourth elimination band includes the Band 53.

This enables the signal in the WLAN 2.4 GHz band and the signal in the Band 41 to be simultaneously transmitted such that the signals can be demultiplexed and enables the signal in the WLAN 2.4 GHz band and the signal in the Band 53 to be simultaneously transmitted such that the signals can be demultiplexed.

### 9. Multiplexer 1A According to Modification

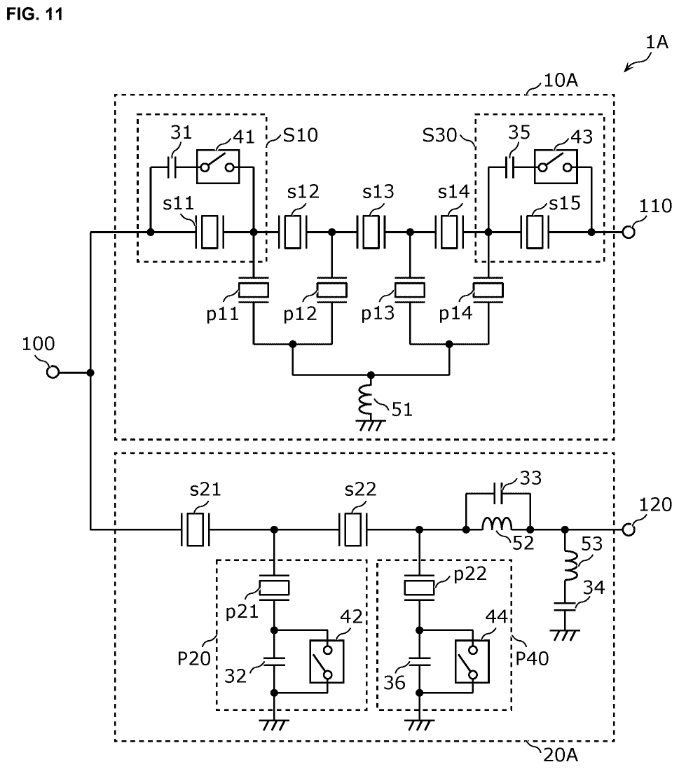

FIG. 11 illustrates an example of a circuit structure of a multiplexer 1A according to a modification to the embodiment. As illustrated in FIG. 11, the multiplexer 1A includes filters 10A and 20A, the common terminal 100, the input-output terminals 110 (the first input-output terminal) and 120 (the second input-output terminal). The multiplexer 1A according to the present modification differs from the multiplexer 1 according to the embodiment in that the filter 10A includes two variable capacitance circuits, and the filter 20A includes two variable capacitance circuits. Accordingly, components of the multiplexer 1A according to the present modification like to those of the multiplexer 1 according to the embodiment will not be described below, but the variable capacitance circuits that are different components will be mainly described.

The filter 10A is an example of the first filter and is connected between the common terminal 100 and the input-output terminal 110. The filter 20A is an example of the second filter and is connected between the common terminal 100 and the input-output terminal 120.

The filter 10A includes the series arm resonators s11, s12, s13, s14, and s15, the parallel arm resonators p11, p12, p13, and p14, the capacitor 31, a capacitor 35, the switch 41, a switch 43, and the inductor 51. The filter 10A differs from the filter 10 according to the embodiment in including the capacitor 35, and the switch 43.

The capacitor 35 is an example of a third capacitor, and the switch 43 is an example of a third switch. The capacitor 35 and the switch 43 are connected in series to each other and form a third variable capacitance circuit. The third variable capacitance circuit is connected in parallel to the series arm resonator s15. The series arm resonator s15, the capacitor 35, and the switch 43 form a series arm resonator unit S30. The series arm resonator s15 is an example of a second series arm resonator and is an acoustic wave resonator to which the third variable capacitance circuit is connected in parallel. The second series arm resonator to which the third variable capacitance circuit is connected in parallel may be any one of the series arm resonators except for the series arm resonator s11.

The filter 20A includes the series arm resonators s21 and s22, the parallel arm resonators p21 and p22, the capacitors 32, 33, and 34, a capacitor 36, the switch 42, a switch 44, and the inductors 52 and 53. The filter 20A differs from the filter 20 according to the embodiment in including the capacitor 36 and the switch 44.

The capacitor 36 is an example of a fourth capacitor, and the switch 44 is an example of a fourth switch. The capacitors 36 and the switch 44 are connected in parallel to each other and form a fourth variable capacitance circuit. The fourth variable capacitance circuit is connected in series to the parallel arm resonator p22. The parallel arm resonator p22, the capacitor 36, and the switch 44 form a parallel arm resonator unit P40. The parallel arm resonator p22 is an example of a second parallel arm resonator and is an acoustic wave resonator to which the fourth variable capacitance circuit is connected in series. The second parallel arm resonator to which the fourth variable capacitance circuit is connected in series may be any one of the parallel arm resonators except for the parallel arm resonator p21.

With the structure described above, the filter 10A serves as, for example, a ladder band pass filter that includes an acoustic wave resonator, and the filter 20A serves as, for example, a ladder band elimination filter that includes an acoustic wave resonator.

As for the multiplexer 1A that has the structure described above, for example, the filter 10A has the first passband that includes the WLAN 2.4 GHz band (2400 to 2482 MHz) in the case where the switches 41 and 43 are in the non-conducting state. For example, the attenuation band higher than the first passband includes the Band 41. For example, the filter 10A has the second passband that includes a part of the WLAN 2.4 GHz band (2400 to 2450 MHz) in the case where the switches 41 and 43 are in the conducting state. For example, the attenuation band higher than the second passband includes the Band 53.

In the case where the switch 43 is in the conducting state, the capacitor 35 is connected in parallel to the series arm resonator s15 at the series arm resonator unit S30, the anti-resonant frequency consequently shifts to a lower frequency, and the resonant band width of the series arm resonator unit S30 decreases. For this reason, in the case where the switch 43 is in the conducting state, the resonant band width of the series arm resonator s15 that defines the high-frequency range of the passband decreases, and consequently, the filter 10A has the second passband that has a high-frequency limit lower than the high-frequency limit of the first passband.

With the structure of the filter 10A described above, not only the series arm resonator s11 but also the series arm resonator s15 has the function of changing the anti-resonant frequency. For this reason, attenuation in the attenuation band close to the high-frequency range of the second passband can be increased.

The anti-resonant frequency of the series arm resonator s15 (the second series arm resonator) to which the third variable capacitance circuit is connected in parallel among the series arm resonators s12 to s15 except for the series arm resonator s11 (the first series arm resonator) may be closest to the anti-resonant frequency of the series arm resonator s11.

This enables attenuation at frequencies close to the anti-resonant frequencies of the series arm resonators s11 and s15 in the attenuation band close to the high-frequency range of the second passband to be increased.

The anti-resonant frequency of the series arm resonator s15 (the second series arm resonator) to which the third variable capacitance circuit is connected in parallel is may not be the lowest among the anti-resonant frequencies of the series arm resonators s11 to s15.

Since the switch 43 is connected in parallel to the series arm resonator s15, there is a possibility that the resonant Q-value of the series arm resonator unit S30 is degraded when the switch 43 is in the non-conducting state. When the anti-resonant frequency of the series arm resonator s15 is separated from the high-frequency limit of the first passband toward the high-frequency range, the insertion loss in the high-frequency range of the first passband can be inhibited from increasing. The use of the multiple series arm resonator units S10 and S30 that have different anti-resonant frequencies enables high attenuation to be ensured in a wide band.

As for the multiplexer 1A that has the structure described above, for example, the filter 20A has the third elimination band that includes the WLAN 2.4 GHz band (2400 to 2482 MHz) in the case where the switches 42 and 44 are in the non-conducting state. For example, the passband higher than the third elimination band includes the Band 41. For example, the filter 20A has the fourth elimination band that includes a part of the WLAN 2.4 GHz band (2400 to 2450 MHz) in the case where the switches 42 and 44 are in the conducting state. For example, the passband higher than the fourth elimination band includes the Band 53.

In the case where the switch 44 is in the conducting state, both ends of the capacitor 36 are short-circuited, and consequently, the resonance characteristics of the parallel arm resonator unit P40 are the same as the resonance characteristics of the parallel arm resonator p22. In this case, the filter 20A has the fourth elimination band that has a high-frequency limit lower than the high-frequency limit of the third elimination band.

With the structure of the filter 20A described above, not only the parallel arm resonator p21 but also the parallel arm resonator p22 have the function of changing the resonant frequency. For this reason, the insertion loss in the passband in the high-frequency range of the fourth elimination band can be reduced.

The resonant frequency of the parallel arm resonator p22 (the second parallel arm resonator) to which the fourth variable capacitance circuit is connected in parallel may be closer than the resonant frequency of the parallel arm resonator p21 (the first parallel arm resonator) to the resonant frequency in the low-frequency range.

The filter 20A changes a band in the high-frequency range of the third elimination band into the passband of the high-frequency range of the fourth elimination band by causing the switches 42 and 44 to be in the conducting state. For this reason, the resonant frequencies of the parallel arm resonators p21 and p22 that have attenuation poles may be separated from the passband described above toward the low-frequency range. This enables the insertion loss in the passband in the high-frequency range of the fourth elimination band to be reduced in a manner in which the resonant frequency of the parallel arm resonator p22 (the second parallel arm resonator) is shifted so as to be closer than the resonant frequency of the parallel arm resonator p21 (the first parallel arm resonator) to the low-frequency range.

As for the multiplexer 1A according to the present modification, the switches 42 and 44 are in the conducting state in the case where the switches 41 and 43 are in the conducting state, and the switches 42 and 44 are in the non-conducting state in the case where the switches 41 and 43 are in the non-conducting state.

The filter 20A may include neither the capacitor 36 nor the switch 44. In this case, the switch 42 is in the conducting state in the case where the switches 41 and 43 are in the conducting state, and the switch 42 is in the non-conducting state in the case where the switches 41 and 43 are in the non-conducting state.

The filters 10A and 20A are not limited by the circuit structure illustrated in FIG. 1, provided that the filter 10A includes the series arm resonator unit S10 and S30 and the one or more parallel arm resonators, and the filter 20A includes the parallel arm resonator unit P20 and the one or more series arm resonators.

The filter 10A may be a band elimination filter, and the filter 20A may be a band pass filter.

### 10. Arrangement of Multiplexer 1

The arrangement of components of the multiplexer 1 according to the present embodiment will now be described.

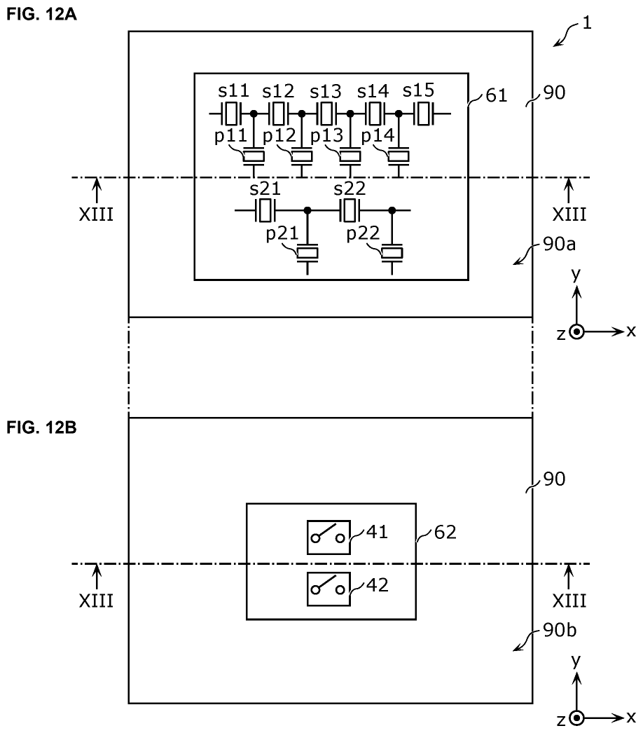

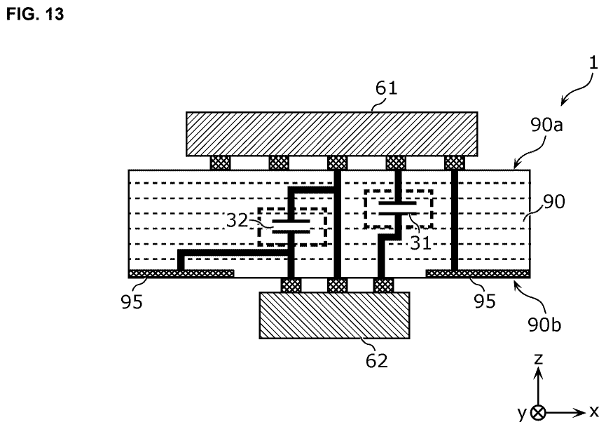

FIG. 12A and FIG. 12B are plan views of the multiplexer 1 according to the embodiment. FIG. 13 is a sectional view of the multiplexer 1 according to the embodiment. FIG. 12A illustrates the arrangement of circuit components when a main surface 90a of a mounting substrate 90 is viewed in the positive direction of the z-axis. FIG. 12B illustrates the arrangement of circuit components when a main surface 90b of the mounting substrate 90 is viewed in the positive direction of the z-axis. FIG. 13 illustrates a sectional view taken along line XIII-XIII in FIG. 12A and FIG. 12B. In FIG. 12A and FIG. 12B and FIG. 13, an illustration for wiring lines that connect the mounting substrate 90 and the circuit components is partly omitted.

The multiplexer 1 illustrated in FIG. 12A and FIG. 12B and FIG. 13 includes the mounting substrate 90 unlike the multiplexer 1 illustrated in FIG. 1.

The mounting substrate 90 has the main surfaces 90a (a first main surface) and 90b (a second main surface) that face away from each other. In FIG. 12A and FIG. 12B, the mounting substrate 90 has a rectangular shape in plan view, but the shape of the mounting substrate 90 is not limited thereto.

Examples of the mounting substrate 90 can include a low temperature co-fired ceramics (LTCC) substrate that has a multilayer structure of multiple dielectric layers, a high temperature co-fired ceramics (HTCC) substrate, a component-embedded board, a substrate that includes a redistribution layer (RDL), or a printed circuit board but are not limited thereto.

An integrated component 61 is disposed in, on, or along the main surface 90a of the mounting substrate 90. An integrated component 62 is disposed in, on, or along the main surface 90b of the mounting substrate 90. The integrated components 61 and 62 are separately disposed on the main surfaces 90a and 90b of the mounting substrate 90, and accordingly, the size of the multiplexer 1 can be decreased. A resin member and a shield electrode layer may be formed on the main surfaces 90a and 90b.

The integrated component 61 is an example of a first integrated component and includes the series arm resonators s11 to s15, the parallel arm resonators p11 to p14, the series arm resonators s21 to s22, and the parallel arm resonators p21 to p22. An example of the integrated component 61 is a single chip for a piezoelectric substrate and a package.

The integrated component 62 includes the switches 41 and 42. For example, the integrated component 62 includes a complementary metal oxide semiconductor (CMOS) and is specifically manufactured by using a silicon-on-insulator (SOI) process. The integrated component 62 is not limited to the CMOS.

As illustrated in FIG. 13, the capacitors 31 and 32 are formed in the mounting substrate 90 by using a planar electrode and a dielectric layer of the mounting substrate 90. An electrode of the capacitor 31 is connected to the integrated component 61, and the other electrode is connected to the integrated component 62. An electrode of the capacitor 32 is connected to the integrated components 61 and 62, and the other electrode is connected to the integrated component 62 and a ground electrode 95 of the mounting substrate 90.

The capacitors 33 and 34 and the inductors 51 to 53 are not illustrated in FIG. 12A and FIGS. 12B and 13 but are disposed on or along the main surface 90a or 90b of the mounting substrate 90 or in the mounting substrate 90.

The integrated component 61 and the integrated component 62 at least partly overlap in plan view of the main surfaces 90a and 90b.

This enables a wiring line that connects the series arm resonator s11 and the switch 41 to each other and a wiring line that connects the parallel arm resonator p21 and the switch 42 to each other to be shortened and accordingly enables the stray capacitance of the wiring lines to be reduced. For this reason, the insertion loss of the filters 10 and 20 can be reduced.

At least a portion of the capacitor 31 may overlap the integrated components 61 and 62 in plan view described above. At least a portion of the capacitor 32 may overlap the integrated components 61 and 62 in plan view described above. This enables a wiring line that connects the series arm resonator s11 and the capacitor 31 to each other and that connects the switch 41 and the capacitor 31 to each other and a wiring line that connects the parallel arm resonator p21 and the capacitor 32 to each other and that connects the switch 42 and the capacitor 32 to each other to be shortened and accordingly enables the stray capacitance of the wiring lines to be reduced. For this reason, the insertion loss of the filters 10 and 20 can be reduced.

### 11. Effects and So On

The multiplexer 1 according to the present embodiment described above includes the common terminal 100, the input-output terminals 110 and 120, the filter 10 the is connected between the common terminal 100 and the input-output terminal 110, and the filter 20 that is connected between the common terminal 100 and the input-output terminal 120, the filter 10 includes one or more series arm resonators s11 to s15 that are disposed on the first series arm path connecting the common terminal 100 and the input-output terminal 110 to each other and that include an acoustic wave resonator, one or more parallel arm resonators p11 to p14 that are connected between the first series arm path and the ground and that include an acoustic wave resonator, and the first variable capacitance circuit connected in parallel to the series arm resonator s11 that is connected and nearest to the common terminal 100 among the series arm resonators s11 to s15, the first variable capacitance circuit includes the capacitor 31 and the switch 41 that are connected in series to each other, the filter 20 includes one or more series arm resonators s21 and s22 that are disposed on the second series arm path connecting the common terminal 100 and the input-output terminal 120 to each other and that include an acoustic wave resonator, one or more parallel arm resonators p21 and p22 that are connected between the second series arm path and the ground and that include an acoustic wave resonator, and the second variable capacitance circuit connected in series to the parallel arm resonator p21 that is connected and nearest to the common terminal 100 among the parallel arm resonators p21 and p22, and the second variable capacitance circuit includes the capacitor 32 and the switch 42 that are connected in parallel to each other.

Consequently, the filter 10 is capable of changing the passband (the elimination band) by switching the conducting state and the non-conducting state of the switch 41, and the filter 20 is capable of changing the passband (the elimination band) by switching the conducting state and the non-conducting state of the switch 42. This enables the passbands (or the elimination bands) of the filters 10 and 20 can be changed together depending on a combination of the bands for simultaneous transmission in the case where signals in two bands that have a narrow frequency gap are simultaneously transmitted. As for the filter 10, the first series arm resonator that is connected and nearest to the common terminal 100 has the function of changing the anti-resonant frequency, and accordingly, the filter 20 most effectively enables the impedance in the passband of the filter 10 to be in the open state. As for the filter 20, the first parallel arm resonator that is connected and nearest to the common terminal 100 has the function of changing the resonant frequency, and accordingly, the filter 10 most effectively enables the impedance in the passband of the filter 20 to be in the open state. For this reason, signals in two bands that have a narrow frequency gap can be simultaneously transmitted such that the signals can be demultiplexed with a low loss.

As for the multiplexer 1, for example, the switch 42 is in the conducting state in the case where the switch 41 is in the conducting state and the switch 42 is in the non-conducting state in the case where the switch 41 is in the non-conducting state.

This enables the limits of the passband (the elimination band) of the filter 10 and the passband (the elimination band) of the filter 20 that are close to each other to be shifted together in the same direction. For this reason, signals in two bands that have a narrow frequency gap can be simultaneously transmitted such that the signals can be demultiplexed.

For example, as for the multiplexer in the first example, the filter 10 is a band pass filter capable of changing the first passband and the second passband that has a high-frequency limit lower than the high-frequency limit of the first passband, and the filter 20 is a band pass filter capable of changing the third passband and the fourth passband that has a low-frequency limit lower than the low-frequency limit of the third passband, the low-frequency limit of the third passband is higher than the high-frequency limit of the first passband, and the low-frequency limit of the fourth passband is higher than the high-frequency limit of the second passband.

This enables the frequency gap between the first passband and the third passband to be ensured in the case where the switches 41 and 42 are in the non-conducting state, and accordingly, the signal that passes through the filter 10 and the signal that passes through the filter 20 can be simultaneously transmitted such that the signals can be demultiplexed. This also enables the frequency gap between the second passband and the fourth passband to be ensured in the case where the switches 41 and 42 are in the conducting state, and accordingly, the signal that passes through the filter 10 and the signal that passes through the filter 20 can be simultaneously transmitted such that the signals can be demultiplexed.

For example, as for the multiplexer in the second example, the filter 10 is a band pass filter capable of changing the first passband and the second passband that has a high-frequency limit lower than the high-frequency limit of the first passband, the filter 20 is a band elimination filter capable of changing the third elimination band and the fourth elimination band that has a high-frequency limit lower than the high-frequency limit of the third elimination band, the frequency of the high-frequency limit of the third elimination band is equal to or higher than the frequency of the high-frequency limit of the first passband, and the frequency of the high-frequency limit of the fourth elimination band is equal to or higher than the frequency of the high-frequency limit of the second passband.

This enables the frequency gap between the first passband and the passband of the filter 20 in the high-frequency range of the third elimination band to be ensured in the case where the switches 41 and 42 are in the non-conducting state, and accordingly, the signal that passes through the filter 10 and the signal that passes through the filter 20 can be simultaneously transmitted such that the signals can be demultiplexed. This also enables the frequency gap between the second passband and the passband of the filter 20 in the high-frequency range of the fourth elimination band to be ensured in the case where the switches 41 and 42 are in the conducting state, and accordingly, the signal that passes through the filter 10 and the signal that passes through the filter 20 can be simultaneously transmitted such that the signals can be demultiplexed.

For example, as for the multiplexer in the third example, the filter 10 is a band elimination filter capable of changing the first elimination band and the second elimination band that has a low-frequency limit lower than the low-frequency limit of the first elimination band, the filter 20 is a band pass filter capable of changing the third passband and the fourth passband that has a low-frequency limit lower than the low-frequency limit of the third passband, the frequency of the low-frequency limit of the first elimination band is equal to or lower than the frequency of the low-frequency limit of the third passband, and the frequency of the low-frequency limit of the second elimination band is equal to or lower than the frequency of the low-frequency limit of the fourth passband.

This enables the frequency gap between the passband of the filter 10 in the low-frequency range of the first elimination band and the third passband to be ensured in the case where the switches 41 and 42 are in the non-conducting state, and accordingly, the signal that passes through the filter 10 and the signal that passes through the filter 20 can be simultaneously transmitted such that the signals can be demultiplexed. This also enables the frequency gap between the passband of the filter 10 in the low-frequency range of the second elimination band and the fourth passband to be ensured in the case where the switches 41 and 42 are in the conducting state, and accordingly, the signal that passes through the filter 10 and the signal that passes through the filter 20 can be simultaneously transmitted such that the signals can be demultiplexed.

For example, the multiplexer in the fourth example, the filter 10 is a band elimination filter capable of changing the first elimination band and the second elimination band that has a low-frequency limit lower than the low-frequency limit of the first elimination band, the filter 20 is a band elimination filter capable of changing the third elimination band and the fourth elimination band that has a high-frequency limit lower than the high-frequency limit of the third elimination band, the low-frequency limit of the first elimination band is lower than the high-frequency limit of the third elimination band, and the low-frequency limit of the second elimination band is lower than the low-frequency limit of the fourth elimination band.

This enables the frequency gap between the passband of the filter 10 in the low-frequency range of the first elimination band and the passband of the filter 20 in the high-frequency range of the third elimination band to be ensured in the case where the switches 41 and 42 are in the non-conducting state, and accordingly, the signal that passes through the filter 10 and the signal that passes through the filter 20 can be simultaneously transmitted such that the signals can be demultiplexed. This also enables the frequency gap between the passband of the filter 10 in the low-frequency range of the second elimination band and the passband of the filter 20 in the high-frequency range of the fourth elimination band to be ensured in the case where the switches 41 and 42 are in the conducting state, and accordingly, the signal that passes through the filter 10 and the signal that passes through the filter 20 can be simultaneously transmitted such that the signals can be demultiplexed.

For example, as for the multiplexer 1A according to the modification, the filter 10A includes the multiple series arm resonators that include the series arm resonator s11, the one or more parallel arm resonators, the first variable capacitance circuit that is connected in parallel to the series arm resonator s11, the third variable capacitance circuit that is connected in parallel to the second series arm resonator among the multiple series arm resonators that are included in the filter 10A except for the series arm resonator s11, and the third variable capacitance circuit includes the capacitor 35 and the switch 43 that are connected in series to each other.

Consequently, not only the series arm resonator s11 but also the second series arm resonator has the function of changing the anti-resonant frequency. For this reason, the attenuation in the attenuation band close to the high-frequency range of the second passband can be increased.

For example, as for the multiplexer 1A according to the modification, the switches 42 and 43 are in the conducting state in the case where the switch 41 is in the conducting state, and the switches 42 and 43 are in the non-conducting state in the case where the switch 41 is in the non-conducting state.

This enables the limits of the passband (the elimination band) of the filter 10A and the passband (the elimination band) of the filter 20A that are close to each other to be shifted together in the same direction. For this reason, signals in two bands that have a narrow frequency gap can be simultaneously transmitted such that the signals can be demultiplexed.

For example, as for the multiplexer 1A according to the modification, the filter 10A includes three or more series arm resonators that include the series arm resonator s11 and the second series arm resonator, and the anti-resonant frequency of the second series arm resonator is closest to the anti-resonant frequency of the series arm resonator s11 among the three or more series arm resonators described above except for the series arm resonator s11.

This enables attenuation at frequencies close to the anti-resonant frequencies of the series arm resonator s11 and the second series arm resonator in the attenuation band close to the high-frequency range of the second passband to be increased.

For example, the multiplexer 1A according to the modification, the filter 20A includes the multiple parallel arm resonators that include the parallel arm resonator p21, the one or more series arm resonators, the second variable capacitance circuit that is connected in series to the parallel arm resonator p21, and the fourth variable capacitance circuit that is connected in series to the second parallel arm resonator among the multiple parallel arm resonators that are included in the filter 20A except for the parallel arm resonator p21, and the fourth variable capacitance circuit includes the capacitor 36 and the switch 44 that are connected in parallel to each other.

Consequently, not only the parallel arm resonator p21 but also the second parallel arm resonator has the function of changing the resonant frequency. For this reason, the insertion loss in the passband in the high-frequency range of the fourth elimination band can be reduced.

For example, as for the multiplexer 1A according to the modification, the switches 42, 43, and 44 are in the conducting state in the case where the switch 41 is in the conducting state, and the switches 42, 43, and 44 are in the non-conducting state in the case where the switch 41 in the non-conducting state.

This enables the limits of the passband (the elimination band) of the filter 10A and the passband (the elimination band) of the filter 20A that are close to each other to be shifted together in the same direction. For this reason, signals in two bands that have a narrow frequency gap can be simultaneously transmitted such that the signals can be demultiplexed.

For example, as for the multiplexer 1A according to the modification, the filter 20A includes three or more parallel arm resonators that include the parallel arm resonator p21 and the second parallel arm resonator, and the resonant frequency of the second parallel arm resonator is closest to the resonant frequency of the parallel arm resonator p21 among the three or more parallel arm resonators described above except for the parallel arm resonator p21.

This enables attenuation at the high-frequency limit of the fourth elimination band to be increased.

For example, the multiplexer 1 further includes the mounting substrate 90 that has the main surfaces 90a and 90b that face away from each other, the one or more series arm resonators that are included in the filter 10, the one or more parallel arm resonators that are included in the filter 10, the one or more series arm resonators that are included in the filter 20, and the one or more parallel arm resonators that are included in the filter 20 are disposed in, on, or along the main surface 90a, and the switches 41 and 42 are disposed in, on, or along the main surface 90b.

Consequently, the switches 41 and 42 and the acoustic wave resonators that are included in the multiplexer 1 are separately disposed on the main surfaces 90a and 90b of the mounting substrate 90, and accordingly, the size of the multiplexer 1 can be decreased.

For example, as for the multiplexer 1, the capacitors 31 and 32 include the dielectric layer and the planar electrode of the mounting substrate 90.

Consequently, the capacitors 31 and 32 are formed in the mounting substrate 90, and accordingly, the size of the multiplexer 1 can be decreased.

For example, as for the multiplexer 1, the one or more series arm resonators that are included in the filter 10, the one or more parallel arm resonators that are included in the filter 10, the one or more series arm resonators that are included in the filter 20, and the one or more parallel arm resonators that are included in the filter 20 are included in the integrated component 61, the switches 41 and 42 are included in the integrated component 62, and the integrated component 61 and the integrated component 62 at least partly overlap in plan view of the main surfaces 90a and 90b.

This enables the wiring line that connects the series arm resonator s11 and the switch 41 to each other and the wiring line that connects the parallel arm resonator p21 and the switch 42 to each other to be shortened, and accordingly, the stray capacitance of the wiring lines can be reduced. For this reason, the insertion loss of the filters 10 and 20 can be reduced.

For example, as for the multiplexer in the first example, the first passband includes at least a part of the Wi-Fi 2.4 GHz band (2400 to 2482 MHz), the third passband includes the Band 41, and the fourth passband includes the Band 53.

For example, as for the multiplexer in the second example, the first passband and the third elimination band include at least a part of the WLAN 2.4 GHz band (2400 to 2482 MHz).

For example, as for the multiplexer in the third example, the first elimination band and the third passband include the Band 41, and the fourth passband includes the Band 53.

For example, as for the multiplexer in the fourth example, the first elimination band includes the Band 41, the second elimination band includes the Band 53, and the third elimination band includes at least a part of the WLAN 2.4 GHz band (2400 to 2482 MHz).

Consequently, the signal in the WLAN 2.4 GHz band and the signal in the Band 41 can be simultaneously transmitted such that the signals can be demultiplexed, and the signal in the WLAN 2.4 GHz band and the signal in the Band 53 can be simultaneously transmitted such that the signals can be demultiplexed.

### Other Embodiments

The multiplexer according to the present disclosure is described above by using the embodiment, the examples, and the modification, but the present disclosure is not limited to the embodiment, the examples, and the modification described above. The present disclosure includes modifications obtained by modifying the embodiment, the examples, and the modification in various ways a person skilled in the art conceives without departing from the spirit of the present disclosure and various devices that include the multiplexer according to the present disclosure.

For example, as for the multiplexer according to the embodiment, the examples, and the modification, matching devices such as an inductor and a capacitor and a switch circuit may be connected between components.

As for the multiplexer according to the embodiment, the examples, and the modification, examples of an acoustic wave resonator include (1) a surface acoustic wave resonator, (2) a bulk acoustic wave resonator, and (3) a laterally excited bulk acoustic resonator (XBAR).

The surface acoustic wave resonator includes (a) a resonator that includes an interdigital transducer (IDT) electrode that is formed in, on, or along a piezoelectric substrate that has a multilayer structure of a support substrate, an intermediate layer (such as a low-acoustic-velocity layer), and a piezoelectric layer and (b) a resonator that includes an IDT electrode that is formed in, on, or along a single-crystal piezoelectric substrate.

The bulk acoustic wave resonator includes (a) a resonator that includes a support substrate that supports a multilayer body that has a piezoelectric layer interposed between two planar electrodes and (b) a solidly mounted resonator (SMR) that includes a multilayer body that has a piezoelectric layer interposed between two planar electrode and that is disposed on an acoustic multilayer film.

The laterally excited bulk acoustic resonator includes (a) a resonator that includes a support substrate that supports a piezoelectric layer including an IDT electrode with a gap interposed therebetween and (b) a resonator that has a piezoelectric layer including an IDT electrode that is disposed on or along an acoustic multilayer film.

The features of the multiplexer described based on the embodiments, the examples, and the modification will be described below.
<1>

A multiplexer includes:

a common terminal;

a first input-output terminal;

a second input-output terminal;

a first filter that is connected between the common terminal and the first input-output terminal; and

a second filter that is connected between the common terminal and the second input-output terminal,

the first filter includes one or more series arm resonators that are disposed on a first series arm path connecting the common terminal and the first input-output terminal to each other and that include an acoustic wave resonator, one or more parallel arm resonators that are connected between the first series arm path and a ground and that include an acoustic wave resonator, and a first variable capacitance circuit connected in parallel to a first series arm resonator that is connected and nearest to the common terminal among the one or more series arm resonators that are included in the first filter,

the first variable capacitance circuit includes a first capacitor and a first switch that are connected in series to each other,

the second filter includes one or more series arm resonators that are disposed on a second series arm path connecting the common terminal and the second input-output terminal to each other and that include an acoustic wave resonator, one or more parallel arm resonators that are connected between the second series arm path and the ground and that include an acoustic wave resonator, and a second variable capacitance circuit connected in series to a first parallel arm resonator that is connected and nearest to the common terminal among the one or more parallel arm resonators that are included in the second filter, and

the second variable capacitance circuit includes a second capacitor and a second switch that are connected in parallel to each other.
<2>

As for the multiplexer described in <1>,

the second switch is in a conducting state in a case where the first switch is in a conducting state, and

the second switch is in a non-conducting state in a case where the first switch is in a non-conducting state.
<3>

As for the multiplexer described in <1> or <2>,

the first filter is a band pass filter capable of changing a first passband and a second passband that has a high-frequency limit lower than a high-frequency limit of the first passband,

the second filter is a band pass filter capable of changing a third passband and a fourth passband that has a low-frequency limit lower than a low-frequency limit of the third passband,

the low-frequency limit of the third passband is higher than the high-frequency limit of the first passband, and

the low-frequency limit of the fourth passband is higher than the high-frequency limit of the second passband.
<4>

As for the multiplexer described in <1> or <2>,

the first filter is a band pass filter capable of changing a first passband and a second passband that has a high-frequency limit lower than a high-frequency limit of the first passband,

the second filter is a band elimination filter capable of changing a third elimination band and a fourth elimination band that has a high-frequency limit lower than a high-frequency limit of the third elimination band,

a frequency of the high-frequency limit of the third elimination band is equal to or higher than a frequency of the high-frequency limit of the first passband, and

a frequency of the high-frequency limit of the fourth elimination band is equal to or higher than a frequency of the high-frequency limit of the second passband.
<5>

As for the multiplexer described in <1> or <2>,

the first filter is a band elimination filter capable of changing a first elimination band and a second elimination band that has a low-frequency limit lower than a low-frequency limit of the first elimination band,

the second filter is a band pass filter capable of changing a third passband and a fourth passband that has a low-frequency limit lower than a low-frequency limit of the third passband,

a frequency of the low-frequency limit of the first elimination band is equal to or lower than a frequency of the low-frequency limit of the third passband, and

a frequency of the low-frequency limit of the second elimination band is equal to or lower than a frequency of the low-frequency limit of the fourth passband.
<6>

As for the multiplexer described in <1> or <2>,

the first filter is a band elimination filter capable of changing a first elimination band and a second elimination band that has a low-frequency limit lower than a low-frequency limit of the first elimination band,

the second filter is a band elimination filter capable of changing a third elimination band and a fourth elimination band that has a high-frequency limit lower than a high-frequency limit of the third elimination band,

the low-frequency limit of the first elimination band is lower than the high-frequency limit of the third elimination band, and

the low-frequency limit of the second elimination band is lower than a low-frequency limit of the fourth elimination band.
<7>

As for the multiplexer described in any one of <1> to <6>,

the first filter includes multiple series arm resonators that include the first series arm resonator,

the one or more parallel arm resonators, the first variable capacitance circuit that is connected in parallel to the first series arm resonator, and a third variable capacitance circuit that is connected in parallel to a second series arm resonator among the multiple series arm resonators that are included in the first filter except for the first series arm resonator, and

the third variable capacitance circuit includes a third capacitor and a third switch that are connected in series to each other.
<8>

As for the multiplexer described in <7>,

the second switch and the third switch are in a conducting state in a case where the first switch is in a conducting state, and

the second switch and the third switch are in a non-conducting state in a case where the first switch is in a non-conducting state.
<9>

As for the multiplexer described in <7> or <8>,

the first filter includes three or more series arm resonators that include the first series arm resonator and the second series arm resonator, and

an anti-resonant frequency of the second series arm resonator is closest to an anti-resonant frequency of the first series arm resonator among the three or more series arm resonators except for the first series arm resonator.
<10>

As for the multiplexer described in any one of <7> to <9>,

the second filter includes multiple parallel arm resonators that include the first parallel arm resonator, the one or more series arm resonators, the second variable capacitance circuit that is connected in series to the first parallel arm resonator, and a fourth variable capacitance circuit that is connected in series to the second parallel arm resonator among the multiple parallel arm resonators that are included in the second filter except for the first parallel arm resonator, and

the fourth variable capacitance circuit includes a fourth capacitor and a fourth switch that are connected in parallel to each other.
<11>

As for the multiplexer described in <10>,

the second switch, the third switch, and the fourth switch are in a conducting state in a case where the first switch is in a conducting state, and

the second switch, the third switch, and the fourth switch are in a non-conducting state in a case where the first switch is in a non-conducting state.
<12>

As for the multiplexer described in <10> or <11>,

the second filter includes three or more parallel arm resonators that include the first parallel arm resonator and the second parallel arm resonator, and

a resonant frequency of the second parallel arm resonator is closest to a resonant frequency of the first parallel arm resonator among the three or more parallel arm resonators except for the first parallel arm resonator.
<13>

The multiplexer described in any one of <1> to <12>, further includes:

a mounting substrate that has a first main surface and a second main surface that face away from each other,

the one or more series arm resonators that are included in the first filter, the one or more parallel arm resonators that are included in the first filter, the one or more series arm resonators that are included in the second filter, and the one or more parallel arm resonators that are included in the second filter are disposed in, on, or along the first main surface, and

the first switch and the second switch are disposed in, on, or along the second main surface.
<14>

As for the multiplexer described in <13>,

the first capacitor and the second capacitor include a dielectric layer and a planar electrode of the mounting substrate.
<15>

As for the multiplexer described in <13> or <14>,

the one or more series arm resonators that are included in the first filter, the one or more parallel arm resonators that are included in the first filter, the one or more series arm resonators that are included in the second filter, and the one or more parallel arm resonators that are included in the second filter are included in a first integrated component,

the first switch and the second switch are included in a second integrated component, and

the first integrated component and the second integrated component at least partly overlap in plan view of the first main surface and the second main surface.
<16>

As for the multiplexer described in <3>, the first passband includes at least a part of a WLAN 2.4 GHz band,

the third passband includes Band 41 for long term evolution (LTE) or n41 for 5th generation new radio (5GNR), and

the fourth passband includes Band 53 for the LTE or n53 for the 5GNR.
<17>

As for the multiplexer described in <4>,

the first passband and the third elimination band include at least a part of a WLAN 2.4 GHz band.
<18>

As for the multiplexer described in <5>,

the first elimination band and the third passband include Band 41 for LTE or n41 for 5GNR, and

the fourth passband includes Band 53 for the LTE or n53 for the 5GNR.
<19>

As for the multiplexer described in <6>,

the first elimination band includes Band 41 for LTE or n41 for 5GNR,

the second elimination band includes Band 53 for the LTE or n53 for the 5GNR, and

the third elimination band includes at least a part of a WLAN 2.4 GHz band.

The present invention can be widely used as a multiplexer that meets a multiband frequency standard for a communication device such as a mobile phone.

What is claimed is:

1. A multiplexer comprising:
a common terminal;
a first input-output terminal;
a second input-output terminal;
a first filter that is connected between the common terminal and the first input-output terminal; and
a second filter that is connected between the common terminal and the second input-output terminal,
wherein the first filter includes one or more series arm resonators that are disposed on a first series arm path connecting the common terminal and the first input-output terminal to each other and that include an acoustic wave resonator, one or more parallel arm resonators that are connected between the first series arm path and a ground and that include an acoustic wave resonator, and a first variable capacitance circuit connected in parallel to a first series arm resonator that is connected and nearest to the common terminal among the one or more series arm resonators that are included in the first filter,
wherein the first variable capacitance circuit includes a first capacitor and a first switch that are connected in series to each other,
wherein the second filter includes one or more series arm resonators that are disposed on a second series arm path connecting the common terminal and the second input-output terminal to each other and that include an acoustic wave resonator, one or more parallel arm resonators that are connected between the second series arm path and the ground and that include an acoustic wave resonator, and a second variable capacitance circuit connected in series to a first parallel arm resonator that is connected and nearest to the common terminal among the one or more parallel arm resonators that are included in the second filter, and
wherein the second variable capacitance circuit includes a second capacitor and a second switch that are connected in parallel to each other.

2. The multiplexer according to claim 1,
wherein the second switch is in a conducting state in a case where the first switch is in a conducting state, and
wherein the second switch is in a non-conducting state in a case where the first switch is in a non-conducting state.

3. The multiplexer according to claim 1,
wherein the first filter is a band pass filter capable of changing a first passband and a second passband that has a high-frequency limit lower than a high-frequency limit of the first passband,
wherein the second filter is a band pass filter capable of changing a third passband and a fourth passband that has a low-frequency limit lower than a low-frequency limit of the third passband,
wherein the low-frequency limit of the third passband is higher than the high-frequency limit of the first passband, and
wherein the low-frequency limit of the fourth passband is higher than the high-frequency limit of the second passband.

4. The multiplexer according to claim 1,
wherein the first filter is a band pass filter capable of changing a first passband and a second passband that has a high-frequency limit lower than a high-frequency limit of the first passband,
wherein the second filter is a band elimination filter capable of changing a third elimination band and a fourth elimination band that has a high-frequency limit lower than a high-frequency limit of the third elimination band,
wherein a frequency of the high-frequency limit of the third elimination band is equal to or higher than a frequency of the high-frequency limit of the first passband, and
wherein a frequency of the high-frequency limit of the fourth elimination band is equal to or higher than a frequency of the high-frequency limit of the second passband.

5. The multiplexer according to claim 1,
wherein the first filter is a band elimination filter capable of changing a first elimination band and a second elimination band that has a low-frequency limit lower than a low-frequency limit of the first elimination band,
wherein the second filter is a band pass filter capable of changing a third passband and a fourth passband that has a low-frequency limit lower than a low-frequency limit of the third passband,
wherein a frequency of the low-frequency limit of the first elimination band is equal to or lower than a frequency of the low-frequency limit of the third passband, and
wherein a frequency of the low-frequency limit of the second elimination band is equal to or lower than a frequency of the low-frequency limit of the fourth passband.

6. The multiplexer according to claim 1,
wherein the first filter is a band elimination filter capable of changing a first elimination band and a second elimination band that has a low-frequency limit lower than a low-frequency limit of the first elimination band,
wherein the second filter is a band elimination filter capable of changing a third elimination band and a fourth elimination band that has a high-frequency limit lower than a high-frequency limit of the third elimination band,
wherein the low-frequency limit of the first elimination band is lower than the high-frequency limit of the third elimination band, and
wherein the low-frequency limit of the second elimination band is lower than a high-frequency limit of the fourth elimination band.

7. The multiplexer according to claim 1,
wherein the first filter includes multiple series arm resonators that include the first series arm resonator, the one or more parallel arm resonators, the first variable capacitance circuit that is connected in parallel to the first series arm resonator, and a third variable capacitance circuit that is connected in parallel to a second series arm resonator among the multiple series arm resonators that are included in the first filter except for the first series arm resonator, and
wherein the third variable capacitance circuit includes a third capacitor and a third switch that are connected in series to each other.

8. The multiplexer according to claim 7,
wherein the second switch and the third switch are in a conducting state in a case where the first switch is in a conducting state, and
wherein the second switch and the third switch are in a non-conducting state in a case where the first switch is in a non-conducting state.

9. The multiplexer according to claim 7,
wherein the first filter includes three or more series arm resonators that include the first series arm resonator and the second series arm resonator, and
wherein an anti-resonant frequency of the second series arm resonator is closest to an anti-resonant frequency of the first series arm resonator among the three or more series arm resonators except for the first series arm resonator.

10. The multiplexer according to claim 7,
wherein the second filter includes multiple parallel arm resonators that include the first parallel arm resonator, the one or more series arm resonators, the second variable capacitance circuit that is connected in series to the first parallel arm resonator, and a fourth variable capacitance circuit that is connected in series to the second parallel arm resonator among the multiple parallel arm resonators that are included in the second filter except for the first parallel arm resonator, and
wherein the fourth variable capacitance circuit includes a fourth capacitor and a fourth switch that are connected in parallel to each other.

11. The multiplexer according to claim 10,
wherein the second switch, the third switch, and the fourth switch are in a conducting state in a case where the first switch is in a conducting state, and
wherein the second switch, the third switch, and the fourth switch are in a non-conducting state in a case where the first switch is in a non-conducting state.

12. The multiplexer according to claim 10,
wherein the second filter includes three or more parallel arm resonators that include the first parallel arm resonator and the second parallel arm resonator, and
wherein a resonant frequency of the second parallel arm resonator is closest to a resonant frequency of the first parallel arm resonator among the three or more parallel arm resonators except for the first parallel arm resonator.

13. The multiplexer according to claim 1, further comprising:
a mounting substrate that has a first main surface and a second main surface that face away from each other,
wherein the one or more series arm resonators that are included in the first filter, the one or more parallel arm resonators that are included in the first filter, the one or more series arm resonators that are included in the second filter, and the one or more parallel arm resonators that are included in the second filter are disposed in, on, or along the first main surface, and
wherein the first switch and the second switch are disposed in, on, or along the second main surface.

14. The multiplexer according to claim 13,
wherein the first capacitor and the second capacitor include a dielectric layer and a planar electrode of the mounting substrate.

15. The multiplexer according to claim 13,
wherein the one or more series arm resonators that are included in the first filter, the one or more parallel arm resonators that are included in the first filter, the one or more series arm resonators that are included in the second filter, and the one or more parallel arm resonators that are included in the second filter are included in a first integrated component,
wherein the first switch and the second switch are included in a second integrated component, and
wherein the first integrated component and the second integrated component at least partly overlap in plan view of the first main surface and the second main surface.

16. The multiplexer according to claim 3,
wherein the first passband includes at least a part of a WLAN 2.4 GHz band,
wherein the third passband includes Band 41 for long term evolution (LTE) or n41 for 5th generation new radio (5GNR), and
wherein the fourth passband includes Band 53 for the LTE or n53 for the 5GNR.

17. The multiplexer according to claim 4,
wherein the first passband and the third elimination band include at least a part of a WLAN 2.4 GHz band.

18. The multiplexer according to claim 5,
wherein the first elimination band and the third passband include Band 41 for LTE or n41 for 5GNR, and
wherein the fourth passband includes Band 53 for the LTE or n53 for the 5GNR.

19. A multiplexer module, comprising:
a mounting substrate having a first main surface and an opposing second main surface;
a first integrated component mounted on the first main surface, the first integrated component including a plurality of acoustic wave resonators forming at least part of a first filter and a second filter coupled to a common terminal; and
a second integrated component mounted on the second main surface, the second integrated component including a first switch and a second switch,
wherein the first filter includes a first series arm resonator of the plurality of acoustic wave resonators, the first series arm resonator being nearest the common terminal, wherein the first switch is electrically coupled in a first variable capacitance circuit connected in parallel with the first series arm resonator; and
wherein the second filter includes a first parallel arm resonator of the plurality of acoustic wave resonators, the first parallel arm resonator being nearest the common terminal, wherein the second switch is electrically coupled in a second variable capacitance circuit connected in series with the first parallel arm resonator.

20. A multiplexer, comprising:
a common terminal;
a first filter having a first signal path between the common terminal and a first input-output terminal, the first filter including a tunable series arm resonator circuit located on the first signal path proximate to the common terminal, the tunable series arm resonator circuit including a series arm acoustic wave resonator and a first switched capacitor connected in parallel with the series arm acoustic wave resonator; and
a second filter having a second signal path between the common terminal and a second input-output terminal, the second filter including a tunable parallel arm resonator circuit coupled between the second signal path and ground proximate to the common terminal, the tunable parallel arm resonator circuit including a parallel arm acoustic wave resonator and a second switched capacitor connected in series with the parallel arm acoustic wave resonator.
